(19) United States
(12) Patent Application Publication
(10) Pub. No.: US 2024/0308028 A1
(43) Pub. Date: Sep. 19, 2024

(54) LIQUID SUPPLY DEVICE AND POLISHING DEVICE

(71) Applicant: EBARA CORPORATION, Tokyo (JP)

(72) Inventors: Noriyuki SATO, Tokyo (JP); Masayuki TAMURA, Tokyo (JP); Kuniaki YAMAGUCHI, Tokyo (JP); Tetsuya TERADA, Tokyo (JP)

(21) Appl. No.: 18/605,311

(22) Filed: Mar. 14, 2024

(30) Foreign Application Priority Data
Mar. 17, 2023 (JP) 2023-042930

(51) Int. Cl. B24B 57/02; B24B 53/017

(52) U.S. Cl. CPC B24B 57/02; B24B 53/017

(57) ABSTRACT

A liquid supply device includes a swing arm capable of horizontally swinging above a polishing table, and a plurality of spray nozzles that is arranged in a longitudinal direction of the swing arm and sprays a cleaning fluid onto the polishing table, in which each of the plurality of spray nozzles has a slit-shaped fluid outlet, and a fluid outlet of the spray nozzle closer to a distal end of the swing arm is oriented to have a larger inclination angle with respect to a longitudinal direction of the swing arm in plan view.

### CROSS-REFERENCE TO RELATED APPLICATIONS

This application claims the benefit of Japanese Priority Patent Application JP 2023-042930 filed on Mar. 17, 2023, the entire contents of which are incorporated herein by reference.

### FIELD

The present technology relates to a liquid supply device and a polishing device.

### BACKGROUND AND SUMMARY

In recent years, as semiconductor devices have been highly integrated, wiring of circuits has become finer, and the distance between wirings has also become narrower. In the manufacture of semiconductor devices, many types of materials are repeatedly formed in a film shape on a silicon wafer to form a stacked structure. In order to form this stacked structure, a technique for flattening the surface of the wafer is important. As a means for planarizing the surface of such a wafer, a polishing device that performs chemical mechanical polishing (CMP) is widely used.

A chemical mechanical polishing (CMP) device generally includes a polishing table to which a polishing pad is attached, a top ring (polishing head) that holds a wafer, and a slurry discharge nozzle that supplies a polishing liquid (slurry) onto the polishing pad. The wafer is pressed against the polishing pad by the top ring while the polishing liquid is supplied from the slurry discharge nozzle onto the polishing pad, and the top ring and the polishing table are moved relative to each other, thereby polishing the wafer to flatten the surface of the wafer.

After the wafer is polished, particles such as polishing chips and abrasive grains contained in the polishing liquid remain on the polishing pad. Therefore, after the wafer is polished, a mist-like cleaning fluid (liquid or mixture of liquid and gas) is sprayed onto the polishing pad from an atomizer having at least one spray nozzle that sprays liquid or mixed fluid of gas and liquid toward the polishing pad, and foreign matters on the polishing pad are removed.

Incidentally, a conventional atomizer is configured to spray the cleaning fluid in a state of being positioned at a predetermined position on the polishing pad. However, as compared with that at the time of design, the cleaning ability of a center portion of a spraying range of the cleaning fluid sprayed from the spray nozzle is high, the cleaning ability of the end portion is insufficient, and a streak residue of the slurry may occur on the pad.

On the other hand, it is considered that the cleaning range can be improved by swinging the atomizer at the time of spraying the cleaning fluid. JP 2022-14055 A proposes a configuration in which a spray nozzle of an atomizer is disposed on the same swing arm as a slurry discharge nozzle as a configuration for swinging the atomizer.

However, the configuration of swinging the atomizer at the time of spraying the cleaning fluid has the following problems.

As illustrated in FIG. 8, when a distal end of an atomizer 120 is moved to a position away from the center of the polishing table 11 by swing of the atomizer 120, an angle of a fluid outlet of a spray nozzle 123 with respect to the rotation direction of the polishing table 11 decreases in a plan view (a water landing region of the cleaning fluid sprayed from the spray nozzle 123 declines in the rotation direction of the polishing table 11 in plan view). Accordingly, as illustrated in FIG. 9, a water landing range (cleaning range) of the cleaning fluid in a radial direction of the polishing table 11 decreases, thereby decreasing the cleaning ability.

As illustrated in FIG. 16, when viewed from the rotation direction of the polishing table 11, an end portion of the water landing region of the cleaning fluid sprayed from the spray nozzle 123 overlaps an end portion of the water landing region of the cleaning fluid sprayed from an adjacent spray nozzle 123 as viewed from the rotation direction of the polishing table 11, and the water landing region of the cleaning fluid swings together with the atomizer 120. Thus, the liquid is hardly discharged from the polishing table 11 (it takes time to discharge the liquid), and hitting power of the cleaning fluid sprayed from the spray nozzle 123 decreases due to the liquid remaining on the polishing table 11.

As illustrated in FIG. 16, covers 125 are provided on both side surfaces of the atomizer 120 in order to suppress mist of the cleaning fluid sprayed from the spray nozzles 123 from spreading into the room, but at the time of high-speed rotation of the polishing table 11, the cleaning fluid flowing to the downstream side in the rotation direction out of the cleaning fluid sprayed from the spray nozzles 123 makes one revolution by the rotation of the polishing table 11 (before being discharged) and returns immediately below the spray nozzles 123. In addition, the cleaning fluid flowing to the upstream side in the rotational direction also receives the rotational force and immediately returns immediately below the spray nozzle 123. Then, these cleaning fluids returning to immediately below the spray nozzle 123 collide with the cleaning fluid newly sprayed from the spray nozzle 123 and become wavy, and then are blocked by the cover 125 on the upstream side in the rotation direction and are accumulated immediately below the spray nozzle 123, and decrease in the hitting power of the cleaning fluid sprayed from the spray nozzle 123 occurs. As illustrated in FIG. 17, the cleaning range in the radial direction of the polishing table 11 changes with time (the cleaning range in the radial direction of the polishing table 11 becomes narrower as the distal end of the atomizer 120 is located farther from the center of the polishing table 11) due to the swing of the atomizer 120, and thus an insufficient cleaning range tends to remain as it is when the hitting power decreases.

In the configuration in which the slurry discharge nozzle and the spray nozzle of the atomizer are disposed on the same swing arm, a dropping position of dressing water is changed by the swing of the swing arm, and thus sufficient dressing water cannot be supplied to the dresser.

It is desirable to provide a technique capable of solving at least one of the above-described problems of the configuration for swinging the atomizer at the time of spraying the cleaning fluid.

A liquid supply device according to an embodiment includes:
a swing arm capable of horizontally swinging above a polishing table; and
a plurality of spray nozzles that is arranged in a longitudinal direction of the swing arm and sprays a cleaning fluid onto the polishing table, in which
each of the plurality of spray nozzles has a slit-shaped fluid outlet, and
a fluid outlet of the spray nozzle closer to a distal end of the swing arm is oriented to have a larger inclination angle with respect to a longitudinal direction of the swing arm in plan view.

### BRIEF DESCRIPTION OF DRAWINGS

FIG. 1 is a plan view illustrating a schematic configuration of a polishing device according to an embodiment;

FIG. 2 is an enlarged perspective view illustrating a liquid supply device included in the polishing device illustrated in FIG. 1;

FIG. 3 is a front view of a swing arm of the liquid supply device illustrated in FIG. 2 as viewed from a distal end side;

FIG. 4 is a view of a distal end portion of the swing arm of the liquid supply device illustrated in FIG. 2 as viewed obliquely from below;

FIG. 5 is a plan view for describing horizontal attachment angles of spray nozzles on the swing arm;

FIG. 6 is a view for describing that liquid on a polishing table passes between water landing regions of a cleaning fluid sprayed from the spray nozzles;

FIG. 7 is a view for describing a cleaning range of a spray nozzle at a horizontal attachment angle illustrated in FIG. 5;

FIG. 8 is a view for describing an example for comparing horizontal attachment angles of the spray nozzles;

FIG. 9 is a view for describing a cleaning range of a spray nozzle at a horizontal attachment angle illustrated in FIG. 8;

FIG. 10 is a view for describing a water landing range of dressing water sprayed from a dressing water nozzle when the swing arm swings;

FIG. 11 is an enlarged perspective view illustrating a modification of the liquid supply device included in the polishing device illustrated in FIG. 1, and is a view for describing a cover having a brush shape;

FIG. 12 is a front view of the swing arm of the liquid supply device illustrated in FIG. 11 as viewed from the distal end side;

FIG. 13 is a view of a distal end portion of the swing arm of the liquid supply device illustrated in FIG. 11 as viewed obliquely from below;

FIG. 14 is a front view of the swing arm of the liquid supply device illustrated in FIG. 11 as viewed from the distal end side, and is a view for describing a state in which a cover having a brush shape is in contact with the polishing table;

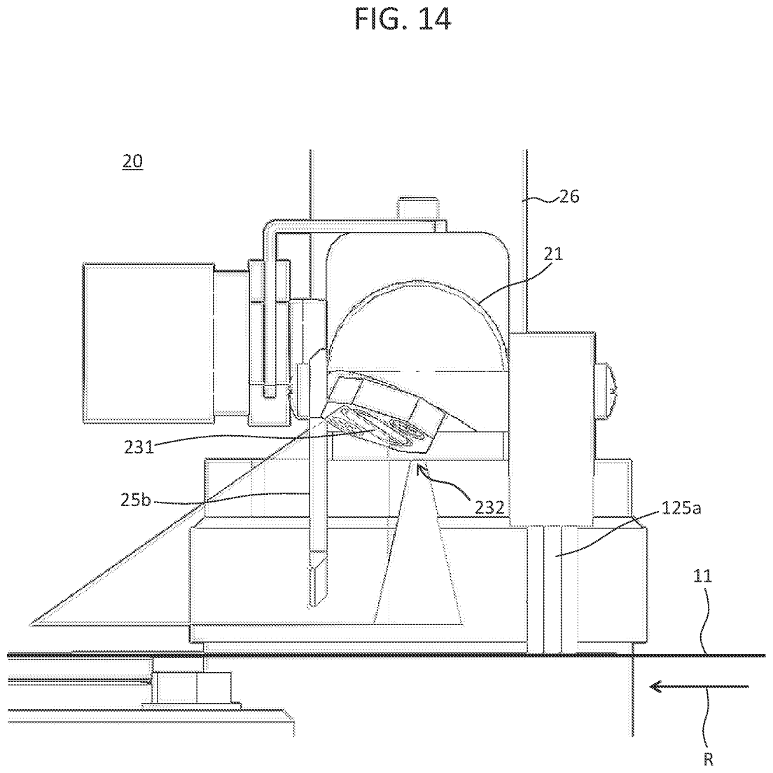

FIG. 15 is a view for describing an aspect in which the spray nozzle is a two-fluid nozzle;

FIG. 16 is a view for describing a configuration for swinging a conventional atomizer for comparison; and

FIG. 17 is a view for describing the configuration for swinging the conventional atomizer for comparison.

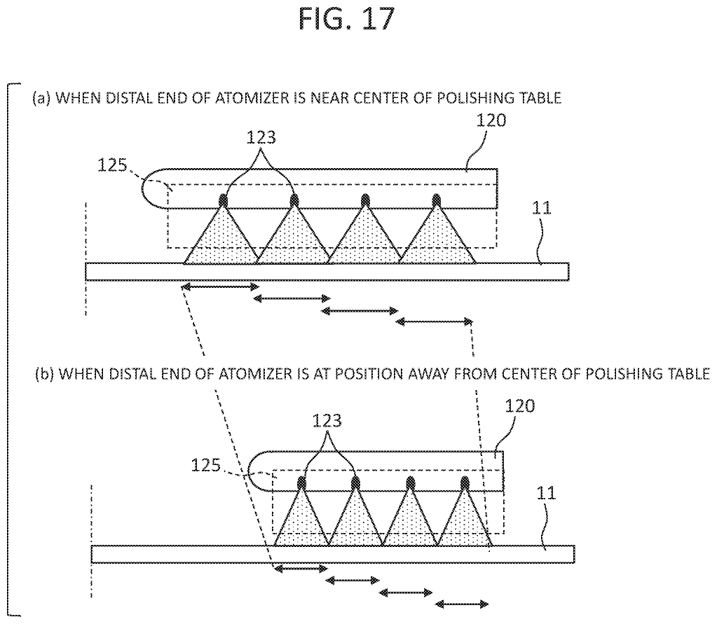

### DETAILED DESCRIPTION OF NON-LIMITING EXAMPLE EMBODIMENTS

A liquid supply device according to a first aspect of the embodiment includes:
a swing arm capable of horizontally swinging above a polishing table; and
a plurality of spray nozzles that is arranged in a longitudinal direction of the swing arm and sprays a cleaning fluid onto the polishing table, in which
each of the plurality of spray nozzles has a slit-shaped fluid outlet, and
a fluid outlet of the spray nozzle closer to a distal end of the swing arm is oriented to have a larger inclination angle with respect to a longitudinal direction of the swing arm in plan view.

According to such an aspect, even when the distal end of the swing arm is at a position farthest from a center of the polishing table in a swing range of the swing arm, an angle of a water landing region of the cleaning fluid sprayed from the spray nozzle with respect to the rotation direction of the polishing table increases, so that the water landing range (cleaning range) of the cleaning fluid in a radial direction of the polishing table can be expanded. In addition, when the distal end of the swing arm is at a position closest to the center of the polishing table in the swing range of the swing arm, an end portion of the water landing region of the cleaning fluid sprayed from the spray nozzle is less likely to overlap an end portion of the water landing region of the cleaning fluid sprayed from the adjacent spray nozzle as viewed from the rotation direction of the polishing table in a region closer to the distal end of the swing arm. Thus, the liquid on the polishing table rotating in the rotation direction easily passes between the water landing regions of the cleaning fluid sprayed from the adjacent spray nozzles, so that the dischargeability of the liquid is improved. By improving the dischargeability of the liquid on the polishing table, it is improved that the hitting power of the cleaning fluid sprayed from the spray nozzle for the liquid remaining on the polishing table decreases. Therefore, the cleaning ability is improved.

A liquid supply device according to a second aspect of the embodiment is the liquid supply device according to the first aspect, in which when the distal end of the swing arm is at a position farthest from a center of the polishing table in a swing range of the swing arm in plan view, the fluid outlet of each of the plurality of spray nozzles is oriented to face the center of the polishing table.

According to such an aspect, when the distal end of the swing arm is at the position farthest from the center of the polishing table in the swing range of the swing arm, the angle of the water landing region of the cleaning fluid sprayed from the spray nozzle with respect to the rotation direction of the polishing table becomes the largest, so that it is possible to widen the water landing range (cleaning range) of the cleaning fluid in the radial direction of the polishing table to the maximum, and it is possible to further improve the cleaning ability.

A liquid supply device according to a third aspect of the embodiment is the liquid supply device according to the first or second aspect, in which
a dressing water nozzle that supplies dressing water onto the polishing table is provided at a distal end of the swing arm, and
the dressing water nozzle is a spray nozzle that sprays the dressing water in a mist form.

According to such an aspect, the water landing range of the dressing water can be expanded, and even when the swing arm swings, the amount of the dressing water toward the center of the polishing table increases, so that a sufficient amount of the dressing water can be supplied to the dresser.

A liquid supply device according to a fourth aspect of the embodiment is the liquid supply device according to the third aspect, in which the dressing water nozzle sprays the dressing water in an oblique direction that is a downstream side in a rotation direction of the polishing table and a distal end side in the longitudinal direction of the swing arm in plan view.

According to such an aspect, the dressing water can be supplied to a position closer to the center of the polishing table, so that the amount of the dressing water supplied to the dresser can be increased.

A liquid supply device according to a fifth aspect of the embodiment is the liquid supply device according to any one of the first to fourth aspects, in which
a cover is provided on both side surfaces of the swing arm so as to cover a space between the spray nozzle and the polishing table, and
the cover located on an upstream side in the rotation direction of the polishing table has a stepped shape as viewed from the longitudinal direction of the swing arm.

According to such an aspect, a space on an upstream side in the rotation direction of the polishing table expands in the space between the spray nozzles and the polishing table covered with the cover, so that the liquid is less likely to be accumulated immediately below the spray nozzle. Thus, decrease in the hitting power of the cleaning fluid sprayed from the spray nozzle is improved, and the cleaning ability is improved.

A liquid supply device according to a sixth aspect of the embodiment is the liquid supply device according to any one of the first to fourth aspects, in which
a cover is provided on both side surfaces of the swing arm so as to cover a space between the spray nozzle and the polishing table, and
the cover located on the upstream side in the rotation direction of the polishing table has a brush shape.

According to such an aspect, when the liquid sprayed from the spray nozzle comes out immediately below the spray nozzle, and when the liquid on the polishing table returns to immediately below the spray nozzle with the rotation of the polishing table, a brush-shaped portion of the cover receives the liquid and weakens the force in the circumferential direction (direction parallel to the rotation direction of the polishing table), so that the liquid spreads thinly on the polishing table, dischargeability of the liquid is improved, and decrease in the hitting power of the cleaning fluid sprayed from the spray nozzle is improved.

A liquid supply device according to a seventh aspect of the embodiment is the liquid supply device according to the sixth aspect, in which the swing arm further includes a moving mechanism that vertically moves the cover between a position in contact with the polishing table and a position separated from the polishing table.

According to such an aspect, when the swing arm is swung, by bringing the cover having a brush shape into contact with the polishing table, it is possible to directly sweep (scrape) deposits on the pad of the polishing table.

A liquid supply device according to an eighth aspect of the embodiment is the liquid supply device according to any one of the first to seventh aspects, in which the spray nozzle is a two-fluid nozzle that sprays a mixed fluid of gas and liquid as a cleaning fluid.

According to such an aspect, by spraying the gas together with the liquid, the liquid remaining on the polishing table is blocked by the gas, and decrease in the hitting power of the sprayed cleaning fluid is prevented. In addition, the momentum of the spray is increased by the amount of the gas, and the cleaning ability is improved by improving the hitting power. Furthermore, the sprayed liquid becomes finer, and thus the sprayed liquid can enter a hole of the pad and can clean therein, so that the cleaning ability is improved.

A polishing device according to a ninth aspect of the embodiment includes the liquid supply device according to any one of the 1 to 8 aspects.

Hereinafter, a specific example of the embodiment will be described with reference to the drawings. In the following description and the drawings used in the following description, the same reference numerals are used for parts that can be configured identically, and redundant description is omitted.

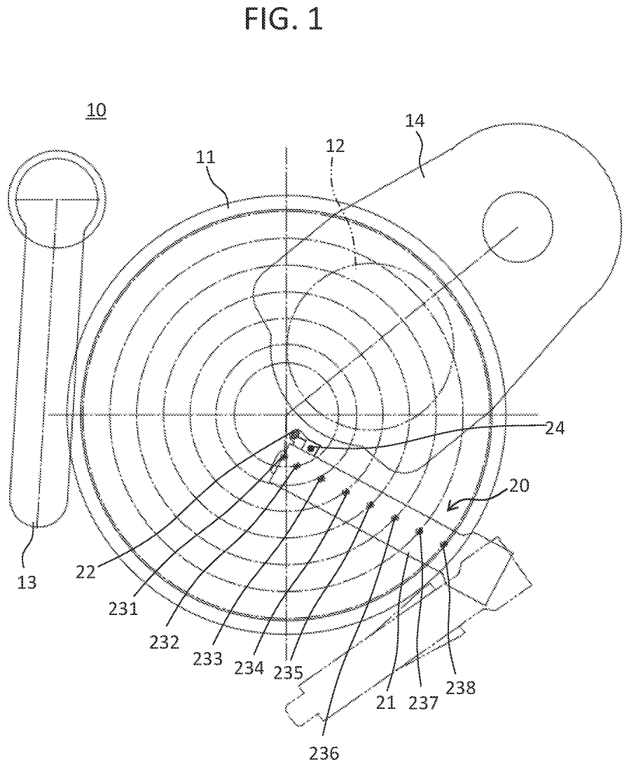

FIG. 1 is a plan view illustrating a schematic configuration of a polishing device 10 according to an embodiment.

As illustrated in FIG. 1, the polishing device 10 includes a polishing table 11 to which a polishing pad (not illustrated) is attached, a top ring (polishing head) 12 for holding a wafer (not illustrated) and polishing the wafer while pressing the wafer against the polishing pad on the polishing table 11, a dresser 13 for dressing the polishing pad, and a liquid supply device 20.

Among them, the top ring 12 is supported by the top ring head 14. A polishing pad (not illustrated) is attached to an upper surface of the polishing table 11, and an upper surface of the polishing pad constitutes a polishing surface for polishing the wafer. Note that a fixed grindstone can be used instead of the polishing pad. The top ring 12 and the polishing table 11 are configured to be rotatable about the respective axes. The wafer is held on the lower surface of the top ring 12 by vacuum suction. At the time of polishing, a polishing liquid (slurry) is supplied from the liquid supply device 20 to the polishing surface of the polishing pad, and the wafer to be polished is pressed against the polishing surface by the top ring 12 and polished.

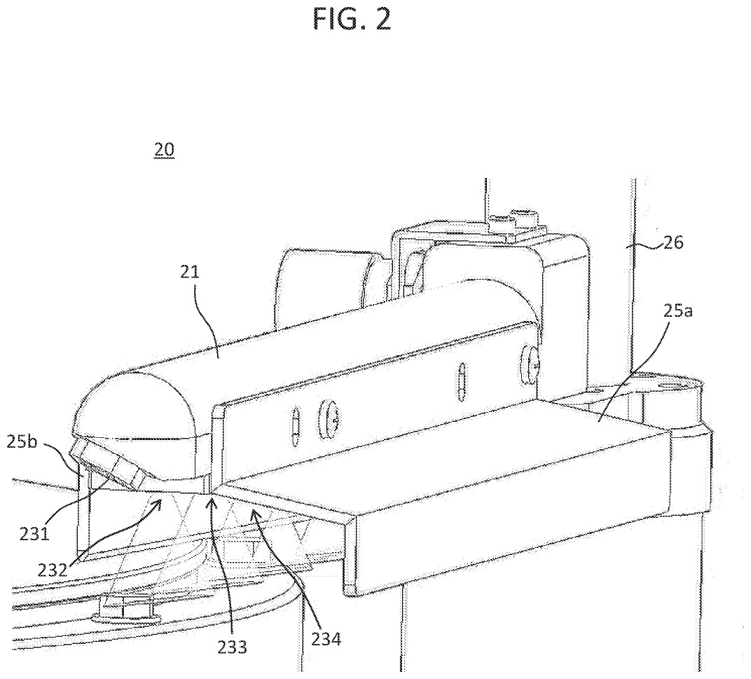

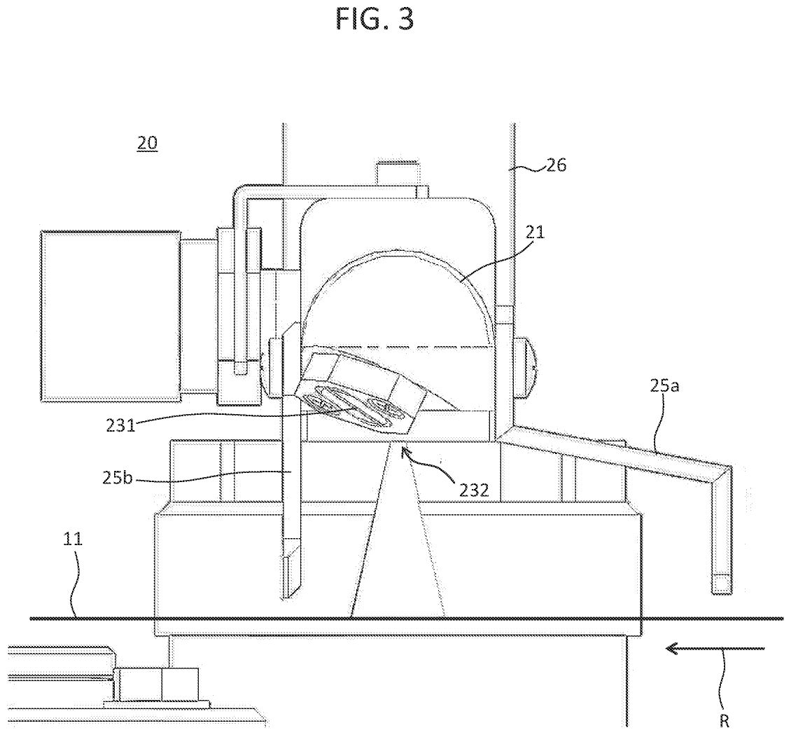

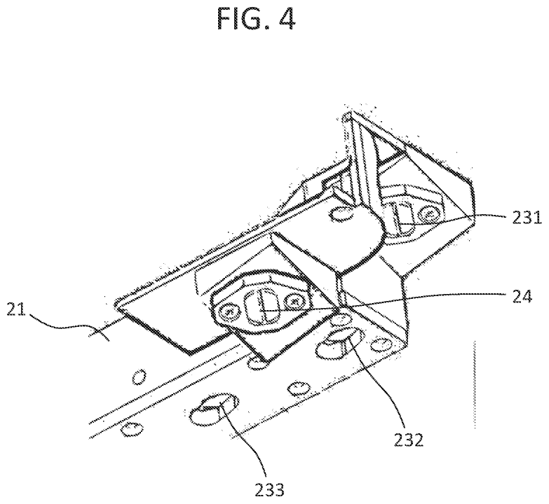

FIG. 2 is an enlarged perspective view illustrating the liquid supply device 20, FIG. 3 is a front view of the swing arm 21 of the liquid supply device 20 as viewed from the distal end side, and FIG. 4 is a view of the distal end portion of the swing arm 21 as viewed obliquely from below.

As illustrated in FIGS. 1 to 4, the liquid supply device 20 includes a swing arm 21 capable of horizontally swinging above the polishing table 11, a plurality of (eight in the example illustrated in FIG. 1) spray nozzles 231 to 238 that is arranged in a longitudinal direction of the swing arm 21 and sprays cleaning fluid (for example, liquid such as pure water or deionized water, or a mixed fluid of liquid and gas (for example, inert gas such as nitrogen gas)) onto the polishing table 11, a slurry discharge nozzle 22 that is provided at the distal end portion of the swing arm 21 and discharges slurry onto the polishing table 11, and a dressing water nozzle 24 that discharges dressing water onto the polishing table 11. Note that, for ease of understanding of the drawings, illustration of the slurry discharge nozzle 22 and the dressing water nozzle 24 is omitted in FIGS. 2 and 3, and illustration of the slurry discharge nozzle 22 is omitted in FIG. 4.

The swing arm 21 is disposed so as to extend horizontally above the polishing table 11, and a swing means is provided at a proximal end portion of the swing arm 21. The swinging means includes a swing shaft 26 extending in the vertical direction and a drive mechanism (for example, a servomotor and a speed reducer) (not illustrated) provided at a lower end portion of the swing shaft 26. The proximal end portion of the swing arm 21 is fixed to the swing shaft 26. When the swing shaft 26 is swung about the vertical central axis by power received from the drive mechanism, the swing arm 21 is horizontally swung (swung) about the swing shaft 26 above the polishing table 11.

As illustrated in FIG. 1, the slurry discharge nozzle 22 and the dressing water nozzle 24 are positioned at the distal end portion of the swing arm 21, and the plurality of spray nozzles 231 to 238 is arranged in the longitudinal direction of the swing arm 21. Here, the distal end portion of the swing arm 21 may be a distal end of the axis (longitudinal direction) of the arm, or may be either one of both side surfaces thereof. In the example illustrated in FIG. 1, the slurry discharge nozzle 22 and the dressing water nozzle 24 are arranged on a side surface on a side facing the wafer held by the top ring 12 in the distal end portion of the swing arm 21.

Each of the plurality of spray nozzles 231 to 238 is disposed on the bottom surface of the swing arm 21. Each of the spray nozzles 231 to 238 has a slit-shaped fluid outlet, atomizes the cleaning fluid, and sprays the atomized cleaning fluid onto the polishing table 11. The entire polishing table 11 can be washed by spraying the cleaning fluid from each of the spray nozzles 231 to 238 while swinging the swing arm 21. The swing angle (swing range) of the swing arm 21 at the time of spraying the cleaning fluid may be, for example, 10° to 20°.

By the way, in the conventional CMP device, the swing arm that swings the slurry discharge nozzle and the atomizer having the spray nozzles are separate bodies, and it is necessary to dispose the slurry discharge nozzle at a height position higher than the atomizer so that the slurry discharge nozzle provided at the distal end portion of the swing arm does not interfere with the atomizer disposed on the polishing pad. Therefore, when the slurry is discharged from the slurry discharge nozzle while the swing arm is swung, the slurry dropping position is likely to be displaced, and it is difficult to drop the slurry necessary for polishing the wafer to an optimum timing and position.

On the other hand, in the present embodiment, since the slurry discharge nozzle 22 and the spray nozzles 231 to 238 are arranged on the same swing arm 21, the slurry discharge nozzle 22 does not interfere with the spray nozzles 231 to 238 even if the height position of the slurry discharge nozzle 22 is lowered. Therefore, the height position of the slurry discharge nozzle 22 can be lowered, whereby the distance and time from when the slurry is discharged from the slurry discharge nozzle 22 to when the slurry reaches on the polishing table 11 are shortened, and when the slurry is discharged from the slurry discharge nozzle 22 while the swing arm 21 is swung, the dropping position of the slurry is less likely to be displaced, and the slurry necessary for polishing the wafer can be dropped at the optimum timing and position.

As illustrated in FIG. 1, in the swing arm 21, the slurry discharge nozzle 22 is disposed closer to the wafer than the spray nozzles 231 to 238. That is, the slurry discharge nozzle 22 is not positioned at an extension of the arrangement of the spray nozzles 231 to 238 (positioned to be shifted toward the wafer side from the extension of the arrangement of the spray nozzles 231 to 238). In still other words, the slurry discharge nozzle 22 is located between the spray nozzle 231 located at the distal end portion of the swing arm 21 and the wafer. Thus, it is possible to discharge the slurry to a position closer to the wafer to be polished, and it is possible to drop the slurry necessary for polishing the wafer at a more optimal timing and to a more optimal position.

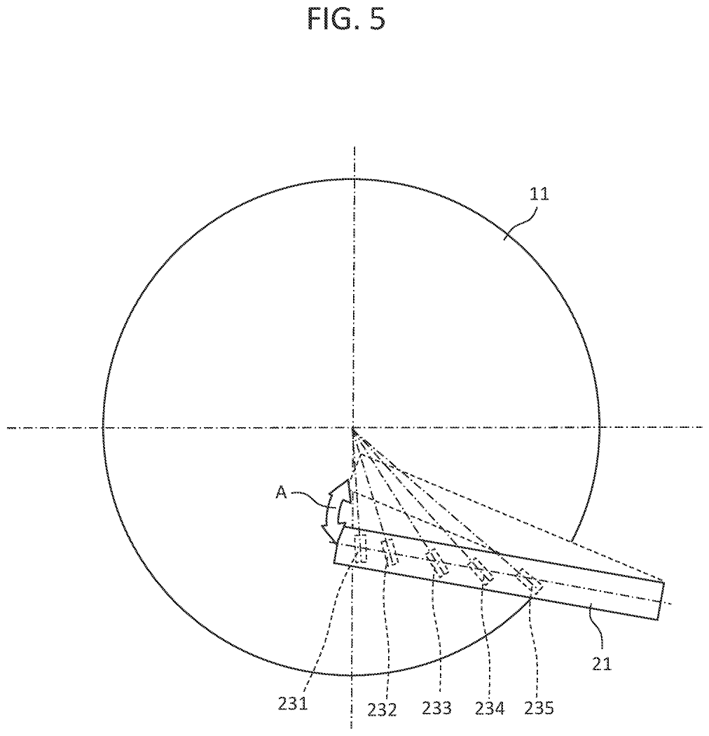

FIG. 5 is a plan view for describing horizontal attachment angles of the spray nozzles 231 to 235 on the swing arm 11. Note that, for ease of understanding of the drawings, the number of the spray nozzles 231 to 235 is reduced in FIG. 5 as compared with FIG. 1.

As illustrated in FIG. 5, in the present embodiment, a fluid outlet of the spray nozzles 231 to 235 closer to the distal end of the swing arm 21 has a larger inclination angle with respect to the longitudinal direction (axis) of the swing arm 21 in plan view.

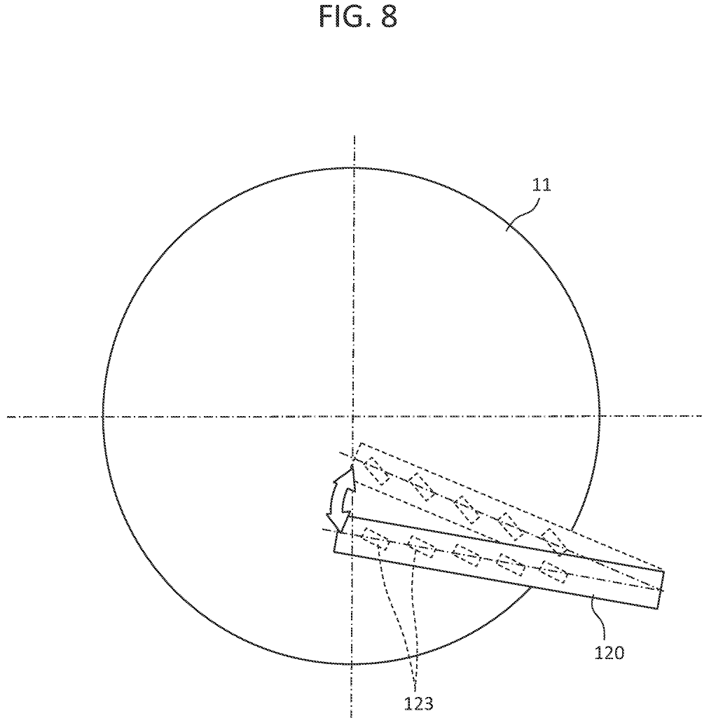

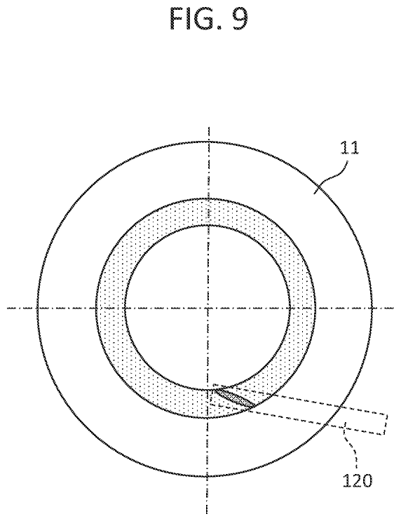

By the way, as a comparative example, as illustrated in FIG. 8, a case will be considered in which the inclination angles of the fluid outlets of the plurality of spray nozzles 123 with respect to the longitudinal direction (axis) of the swing arm 120 are the same in plan view. In this case, when the distal end of the swing arm 120 is moved to a position away from the center of the polishing table 11 by swing of the swing arm 120, the angle with respect to the rotation direction of the polishing table 11 becomes smaller (the water landing region of the cleaning fluid sprayed from the spray nozzle 123 declines in the rotation direction of the polishing table 11 in plan view) as the fluid outlet of the spray nozzle is closer to the distal end of the swing arm 120. Accordingly, as illustrated in FIG. 9, the water landing range (cleaning range) of the cleaning fluid in the radial direction of the polishing table 11 becomes narrower, and thus the cleaning ability decreases.

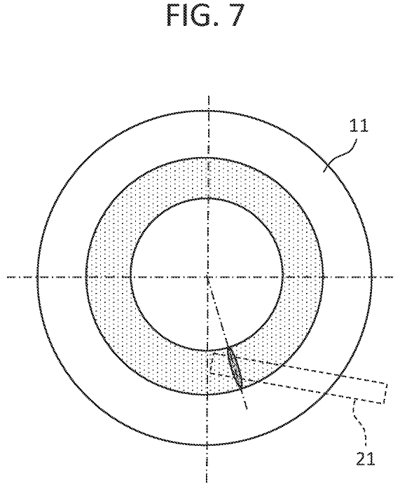

On the other hand, in the present embodiment, the fluid outlet of the spray nozzle closer to the distal end of the swing arm 21 is oriented to have a larger inclination angle with respect to the longitudinal direction (axis) of the swing arm 21 in plan view, and thus, as illustrated in FIG. 5, even when the distal end of the swing arm 21 is at a position farthest from the center of the polishing table 11 in the swing range A of the swing arm 21, the angle of the water landing region of the cleaning fluid sprayed from the spray nozzles 231 to 235 with respect to the rotation direction of the polishing table 11 is larger, whereby the water landing range (cleaning range) of the cleaning fluid in the radial direction of the polishing table 11 can be widened as illustrated in FIG. 7.

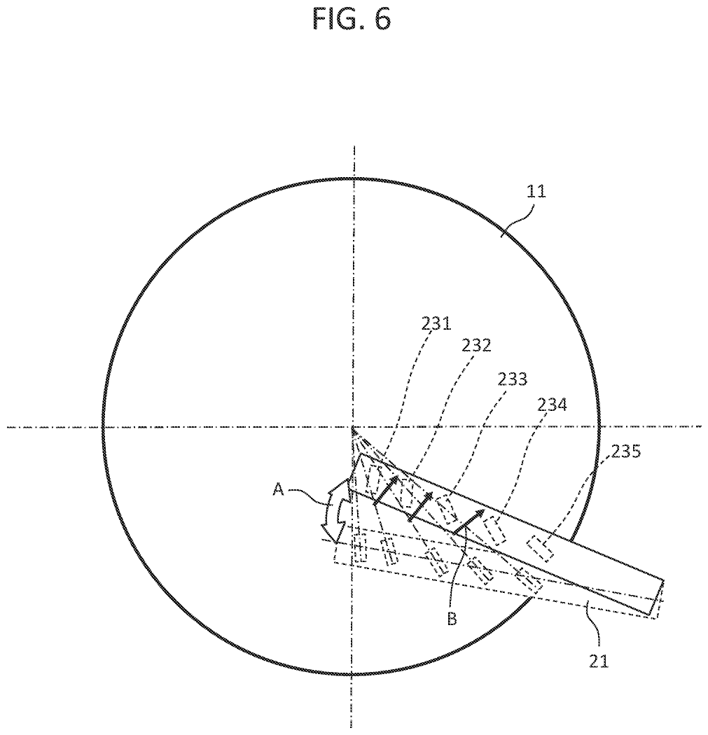

Further, in the present embodiment, the fluid outlet of the spray nozzle closer to the distal end of the swing arm 21 is oriented to have a larger inclination angle with respect to the longitudinal direction (axis) of the swing arm 21 in plan view, and thus, as illustrated in FIG. 6, when the distal end of the swing arm 21 in the swing range A of the swing arm 21 is at a position closest to the center of the polishing table 11, the end portion of the water landing region of the cleaning fluid sprayed from the spray nozzle is less likely to overlap the end portion of the water landing region of the cleaning fluid sprayed from the adjacent spray nozzle as viewed from the rotation direction of the polishing table 21 as the spray nozzle is closer to the distal end of the swing arm 21. Thus, as indicated by the arrow B in FIG. 6, the liquid on the polishing table 11 rotating in the rotation direction (counterclockwise in FIG. 6) easily passes between the water landing regions of the cleaning fluid sprayed from the adjacent spray nozzles 231 to 235, so that the dischargeability of the liquid is improved. By improving the dischargeability of the liquid on the polishing table 11, it is improved that the hitting power of the cleaning fluid sprayed from the spray nozzles 231 to 235 for the liquid remaining on the polishing table 11 decreases.

As illustrated in FIG. 5, when the distal end of the swing arm 21 is at a position farthest from the center of the polishing table 11 in the swing range A of the swing arm 21 in plan view, the fluid outlet of each of the plurality of spray nozzles 231 to 235 may be oriented to face the center of the polishing table 11 (so as to be parallel to the radial direction of the polishing table 11). In this case, when the distal end of the swing arm 21 is at the position farthest from the center of the polishing table 11 in the swing range A of the swing arm 21, the angle of the water landing region of the cleaning fluid sprayed from the spray nozzles 231 to 235 with respect to the rotation direction of the polishing table 11 becomes the largest (becomes 90°), so that the water landing range (cleaning range) of the cleaning fluid in the radial direction of the polishing table 11 can be expanded to the maximum.

As illustrated in FIGS. 2 to 4, the spray nozzle 231 located at the distal end portion of the swing arm 21 may be provided obliquely so as to clean the dropping position of the slurry discharged from the slurry discharge nozzle 22 on the polishing table 11. That is, when viewed from the distal end side of the swing arm 21, the spray nozzle 231 positioned at the distal end portion of the swing arm 21 may be provided obliquely so that an extension line of the discharge direction thereof forms an acute angle with respect to an extension line of the discharge direction of the slurry discharge nozzle 22.

With reference to FIG. 1, for example, in a case where the slurry is dropped from the slurry discharge nozzle 22 to the vicinity of the center of the polishing table 11, if the spray nozzle 231 positioned at the distal end portion of the swing arm 21 is provided vertically downward, there is a possibility that cleaning fluid cannot be sufficiently sprayed to clean the slurry remaining in the vicinity of the center of the polishing table 11. The reason why the slurry tends to remain near the center is that the centrifugal force directed to the outer periphery of the polishing table with respect to the slurry is less likely to work toward the radial center of the polishing table. On the other hand, in the present embodiment, since the spray nozzle 231 located at the distal end portion of the swing arm 21 is provided obliquely so as to be able to clean the dropping position of the slurry discharged from the slurry discharge nozzle 22, even when the slurry is dropped from the slurry discharge nozzle 22 to the vicinity of the center of the polishing table 11, it is possible to sufficiently spray the cleaning fluid to the vicinity of the center of the polishing table 11 for cleaning, and it is possible to reduce particles remaining on the polishing table 11.

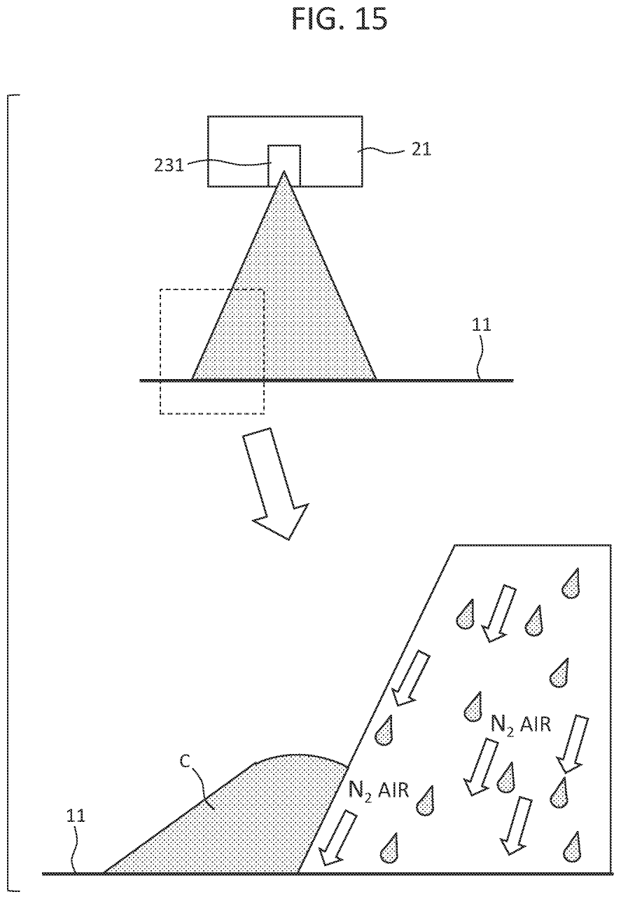

As illustrated in FIG. 15, each of the spray nozzles 231 to 238 may be a two-fluid nozzle that sprays a mixed fluid of gas and liquid as a cleaning fluid. In this case, since the gas is sprayed together with the liquid from the spray nozzles 231 to 238, liquid C remaining on the polishing table 11 is blocked by the gas, and thus decrease in the hitting power of the cleaning fluid sprayed from the spray nozzles 231 to 238 is prevented. In addition, the momentum of the spray is increased by the amount of the gas, and the cleaning ability is improved by improving the hitting power. Furthermore, the sprayed liquid becomes finer, and thus the sprayed liquid can enter a hole of the pad on the polishing table 11 and can clean therein, so that the cleaning ability is improved.

As illustrated in FIGS. 2 and 3, covers 25a and 25b may be provided on both side surfaces of the swing arm 21 so as to cover the space between the spray nozzles 231 to 238 and the polishing table 11 in order to suppress the mist of the cleaning fluid sprayed from the spray nozzles 231 to 238 from spreading in the room.

As an example, as illustrated in FIGS. 2 and 3, the cover 25a located on the upstream side in a rotation direction R of the polishing table 11 may have a stepped shape as viewed from the longitudinal direction of the swing arm 11, and in the space between the spray nozzles 231 to 238 and the polishing table 11 covered by the covers 25a and 25b, a space on the upstream side in the rotation direction R of the polishing table 11 may be expanded.

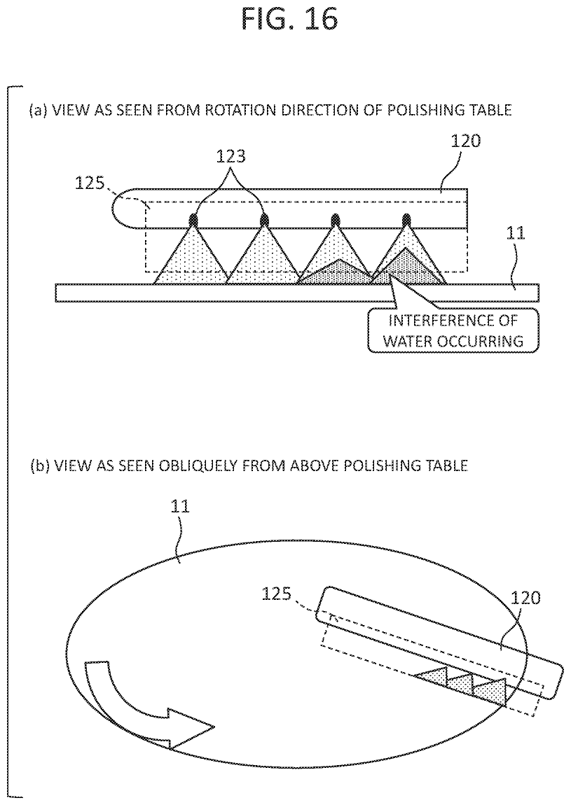

However, as a comparative example, a case will be considered where the cover 25a located on the upstream side in the rotation direction R of the polishing table 11 has a flat plate shape extending directly downward from the side surface of the swing arm 120, similarly to the cover 25b located on the downstream side. As illustrated in FIG. 16, at the time of high-speed rotation of the polishing table 11, the cleaning fluid sprayed from the spray nozzle 123 returns to immediately below the spray nozzle 123 by one turn due to the rotation of the polishing table 11 (before being discharged to the outside of the polishing table 11), and may collide with the cleaning fluid newly sprayed from the spray nozzle 123 and become wavy, but in a case where the cover 125 on the upstream side in the rotation direction R has a flat plate shape extending directly downward from the swing arm 120, the wavy liquid is blocked by the cover 125 on the upstream side in the rotation direction R and accumulates immediately below the spray nozzle 123, and thus the hitting power of the cleaning fluid sprayed from the spray nozzle 123 decreases.

On the other hand, in the present embodiment, the cover 25a on the upstream side in the rotation direction R has a stepped shape, and in the space between the spray nozzles 231 to 238 and the polishing table 11 covered by the covers 25a and 25b, the space on the upstream side in the rotation direction R expands so that the liquid is less likely to be accumulated immediately below the spray nozzles 231 to 238. Thus, decrease in the hitting power of the cleaning fluid sprayed from the spray nozzles 231 to 238 is improved, and the cleaning ability can be improved.

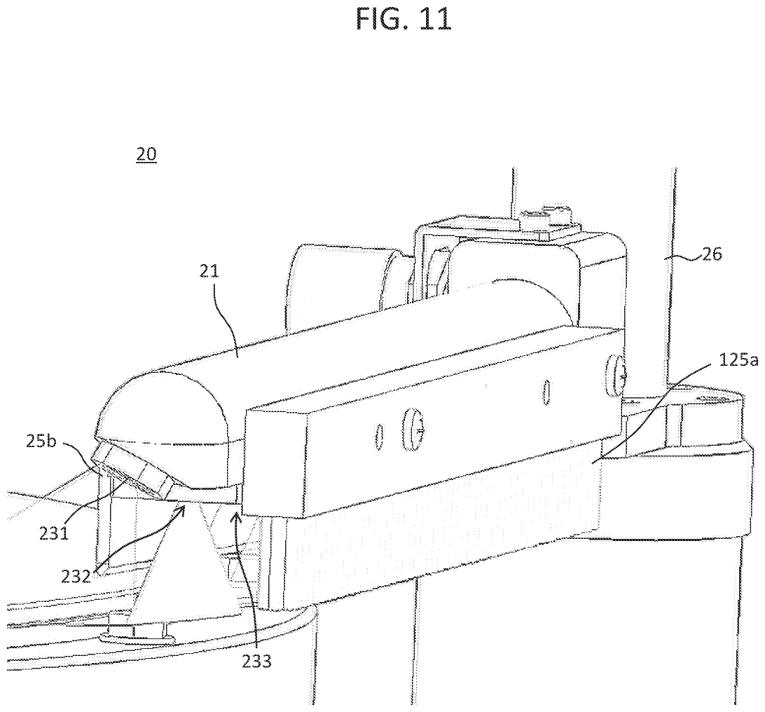

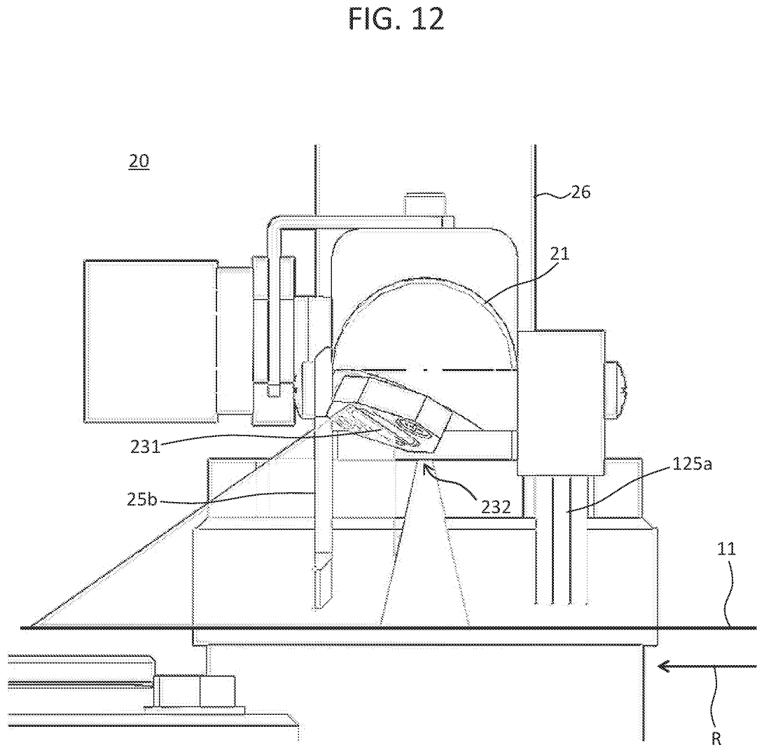

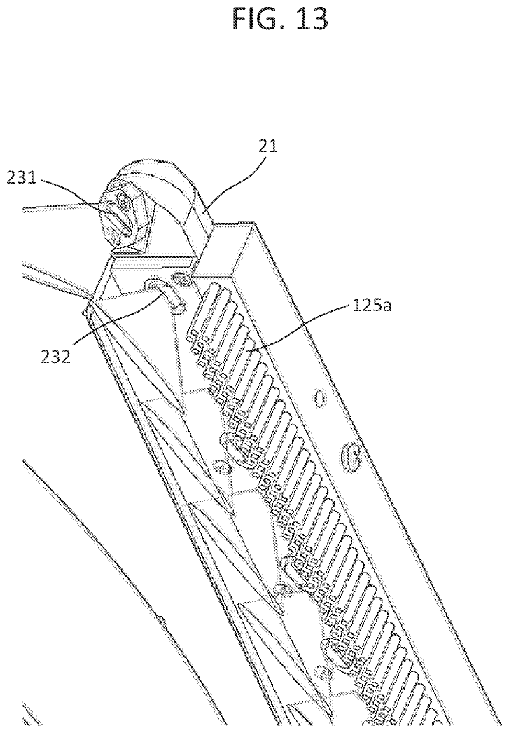

As a modification, as illustrated in FIGS. 11 to 13, the cover 25a located on the upstream side in the rotation direction R of the polishing table 11 may have a brush shape. In this case, when the liquid sprayed from the spray nozzles 231 to 238 comes out immediately below the spray nozzles 231 to 238 and when the liquid of the polishing table 11 returns to immediately below the spray nozzles 231 to 238 with the rotation of the polishing table 11, the brush-shaped portion of the cover 26a receives the liquid and weakens the force in the circumferential direction (direction parallel to the rotation direction of the polishing table), so that the liquid thinly spreads on the polishing table 11. Thus, the dischargeability of the liquid from the polishing table 11 is enhanced, and decrease in the hitting power of the cleaning fluid sprayed from the spray nozzles 231 to 238 is improved.

When the cover 25a located on the upstream side in the rotation direction R of the polishing table 11 has a brush shape, the swing arm 21 may be provided with a moving mechanism (not illustrated) that vertically moves the cover 25a having a brush shape between a position in contact with the polishing table and a position separated from the polishing table 11. The moving mechanism may have an air cylinder or a motor, or may be manual. When the swing arm 21 is swung while the cleaning fluid is sprayed from the spray nozzles 231 to 238, the cover 25a having a brush shape is lowered by the moving mechanism and brought into contact with the polishing table 11, whereby deposits on the pad of the polishing table 11 can be directly swept (scraped), and the cleaning ability of the pad is further improved.

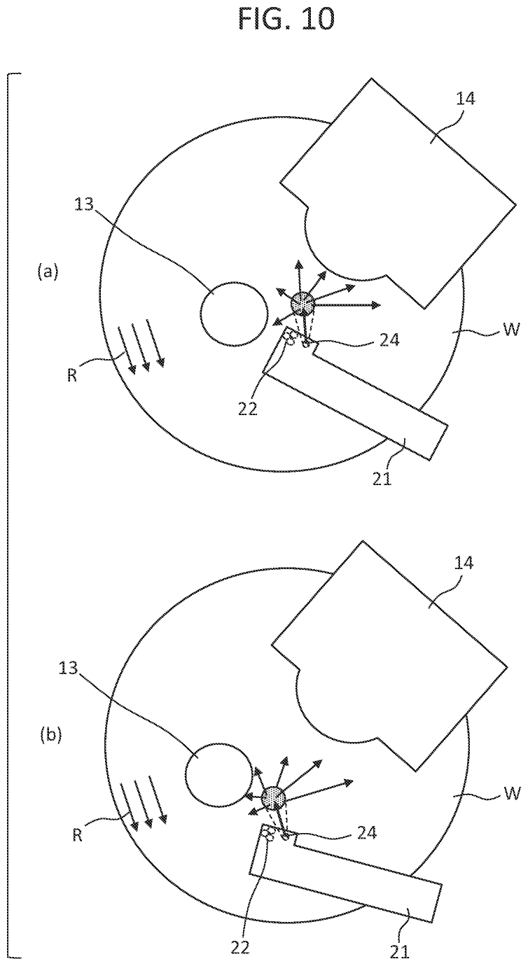

Next, a configuration of the dressing water nozzle 24 will be described. As illustrated in FIGS. 1 and 4, the dressing water nozzle 22 is provided adjacent to the slurry discharge nozzle 22 at the distal end portion of the swing arm 11, and supplies the dressing water to a dresser 33 (or the wafer held by the top head 12) arranged on the polishing table 11 as illustrated in FIG. 10 at the time of dressing of the polishing pad (or at the time of water cleaning of the wafer).

As illustrated in FIG. 4, the dressing water nozzle 22 has a slit-shaped fluid outlet, and may be a spray nozzle that sprays the dressing water in a mist form. In this case, as compared with a configuration in which the liquid is directly dropped downward from a pipe as in the slurry discharge nozzle 22, the water landing range of the dressing water can be expanded, and as illustrated in FIG. 10, even if the swing arm 21 swings, the amount of the dressing water toward the center of the polishing table 11 increases, so that a sufficient amount of the dressing water can be supplied to the dresser 13 (or the wafer held by the top head 12).

As illustrated in FIG. 4, the dressing water nozzle 22 is provided obliquely with respect to the vertical direction and, as illustrated in FIG. 10, may be configured to spray the dressing water in an oblique direction that is the downstream side in the rotation direction of the polishing table 11 and the distal end side in the longitudinal direction of the swing arm 12 in plan view. In this case, since the dressing water can be supplied to a position closer to the center of the polishing table 11, the amount of the dressing water supplied to the dresser 13 (or the wafer held by the top head 12) can be increased.

Next, an example of operation of the polishing device 10 configured as described above will be described.

First, at the time of polishing the wafer, as illustrated in FIG. 1, in a state where the swing arm 21 is positioned so that the slurry can be dropped from the slurry discharge nozzle 22 to the vicinity of the center of the polishing table 11, the slurry is discharged from the slurry discharge nozzle 22 onto the polishing table 11, and the wafer to be polished is pressed onto the polishing table 11 by the top ring 12 and polished.

After the wafer is polished, the slurry discharge from the slurry discharge nozzle 22 is stopped. Next, as illustrated in FIGS. 5 and 6, while the swing arm 21 is swung in a predetermined swing range A, a mist-like cleaning fluid is sprayed from each of the spray nozzles 231 to 238 onto the polishing table 11 to clean the polishing table 11, and dressing water is supplied from the dressing water nozzle 24 onto the polishing table 11 to perform dressing of the polishing pad (or water cleaning of the wafer) as illustrated in FIG. 10. The spray of the fluid from each of the spray nozzles 231 to 238 and the dressing water nozzle 24 is performed until before the start of polishing of the next wafer (until completion of the dressing operation).

According to the present embodiment as described above, the fluid outlet of the spray nozzle 231 to 238 closer to the distal end of the swing arm 21 is oriented to have a larger inclination angle with respect to the longitudinal direction (axis) of the swing arm 21 in plan view, and thus, as illustrated in FIG. 5, even when the distal end of the swing arm 21 is at a position farthest from the center of the polishing table 11 in the swing range A of the swing arm 21, the angle of the water landing region of the cleaning fluid sprayed from the spray nozzles 231 to 238 with respect to the rotation direction of the polishing table 11 is larger, whereby the water landing range (cleaning range) of the cleaning fluid in the radial direction of the polishing table 11 can be widened as illustrated in FIG. 7. In addition, as illustrated in FIG. 6, when the distal end of the swing arm 21 is at a position closest to the center of the polishing table 11 in the swing range A of the swing arm 21, the end portion of the water landing region of the cleaning fluid sprayed from the spray nozzle 231 to 238 is less likely to overlap the end portion of the water landing region of the cleaning fluid sprayed from the adjacent spray nozzle 231 to 238 as viewed from the rotation direction of the polishing table 11 in a region closer to the distal end of the swing arm 21. Thus, the liquid on the polishing table 11 rotating in the rotation direction easily passes between the water landing regions of the cleaning fluid sprayed from the adjacent spray nozzles 231 to 238, so that the dischargeability of the liquid is improved. By improving the dischargeability of the liquid on the polishing table 11, it is improved that the hitting power of the cleaning fluid sprayed from the spray nozzle for the liquid remaining on the polishing table decreases. Therefore, the cleaning ability is improved.

In addition, according to the present embodiment, since the dressing water nozzle 24 is a spray nozzle that sprays the dressing water in a mist form, the water landing range of the dressing water can be expanded, and the amount of dressing water flowing toward the center of the polishing table 11 can be increased even when the swing arm 21 swings. Thus, as illustrated in FIG. 10, a sufficient amount of dressing water can be supplied to the dresser 13 arranged on the polishing table 11.

In addition, according to one aspect of the present embodiment, since the cover 25a located on the upstream side in the rotation direction R of the polishing table 11 has a stepped shape, the space on the upstream side in the rotation direction R of the polishing table 11 expands in the space between the spray nozzles 231 to 238 and the polishing table 11 covered by the covers 24a and 24b, and the liquid is less likely to be accumulated immediately below the spray nozzles 231 to 238. Thus, decrease in the hitting power of the cleaning fluid sprayed from the spray nozzles 231 to 238 is improved, and the cleaning ability is further improved.

In addition, according to another aspect of the present embodiment, since the cover 25a located on the upstream side in the rotation direction R of the polishing table 11 has a brush shape, when the liquid sprayed from the spray nozzles 231 to 238 comes out immediately below the spray nozzles 231 to 238 and when the liquid on the polishing table 11 returns to immediately below the spray nozzles 231 to 238 along with the rotation of the polishing table 231 to 238, the brush-shaped portion of the cover 25a can receive the liquid and weaken the force in the circumferential direction (direction parallel to the rotation direction of the polishing table 11). Thus, the liquid spreads thinly on the polishing table 11, the dischargeability of the liquid is enhanced, and decrease in the hitting power of the cleaning fluid sprayed from the spray nozzles 231 to 238 is further improved.

In addition, according to the present embodiment, since the spray nozzles 231 to 238 are two-fluid nozzles that spray a mixed fluid of gas and liquid as the cleaning fluid, the liquid remaining on the polishing table 11 is blocked by the gas at the time of spraying the cleaning fluid, and decrease in the hitting power of the cleaning fluid is prevented. In addition, the momentum of the spray is increased by the amount of the gas, and the cleaning ability is improved by improving the hitting power. Furthermore, the sprayed liquid becomes finer, and thus the sprayed liquid can enter a hole of the pad and can clean therein, so that the cleaning ability is improved.

Although the embodiments and modifications of the present technology have been described above by way of example, the scope of the present technology is not limited thereto, and can be changed and modified according to the purpose within the scope described in the claims. In addition, the embodiments and the modifications can be appropriately combined within a range in which the processing contents do not contradict each other.

What is claimed is:

1. A liquid supply device comprising:
a swing arm capable of horizontally swinging above a polishing table; and
a plurality of spray nozzles that is arranged in a longitudinal direction of the swing arm and sprays a cleaning fluid onto the polishing table, wherein
each of the plurality of spray nozzles has a slit-shaped fluid outlet, and
a fluid outlet of the spray nozzle closer to a distal end of the swing arm is oriented to have a larger inclination angle with respect to a longitudinal direction of the swing arm in plan view.

2. The liquid supply device according to claim 1, wherein when the distal end of the swing arm is at a position farthest from a center of the polishing table in a swing range of the swing arm, the fluid outlet of each of the plurality of spray nozzles is oriented to face the center of the polishing table in plan view.

3. The liquid supply device according to claim 1, wherein
a dressing water nozzle that supplies dressing water onto the polishing table is provided at a distal end of the swing arm, and
the dressing water nozzle is a spray nozzle that sprays the dressing water in a mist form.

4. The liquid supply device according to claim 3, wherein the dressing water nozzle sprays the dressing water in an oblique direction that is a downstream side in a rotation direction of the polishing table and a distal end side in the longitudinal direction of the swing arm in plan view.

5. The liquid supply device according to claim 1, wherein
a cover is provided on both side surfaces of the swing arm so as to cover a space between the spray nozzle and the polishing table, and
the cover located on an upstream side in the rotation direction of the polishing table has a stepped shape as viewed from the longitudinal direction of the swing arm.

6. The liquid supply device according to claim 1, wherein
a cover is provided on both side surfaces of the swing arm so as to cover a space between the spray nozzle and the polishing table, and
the cover located on the upstream side in the rotation direction of the polishing table has a brush shape.

7. The liquid supply device according to claim 6, wherein the swing arm further includes a moving mechanism that vertically moves the cover between a position in contact with the polishing table and a position separated from the polishing table.

8. The liquid supply device according to claim 1, wherein the spray nozzle is a two-fluid nozzle that sprays a mixed fluid of gas and liquid as a cleaning fluid.

9. A polishing device comprising the liquid supply device according to claim 1.
